(19) United States
(12) Patent Application Publication
(10) Pub. No.: US 2025/0314680 A1
(43) Pub. Date: Oct. 9, 2025

(54) VOLTAGE DETECTION CIRCUIT, VOLTAGE MONITORING CIRCUIT, AND POWER SUPPLY AND CONTROL CIRCUIT THEREOF

(71) Applicant: Joulwatt Technology (Shanghai) Co., Ltd., Shanghai (CN)

(72) Inventors: Linjue LI, Shanghai (CN); Naixia JIU, Shanghai (CN)

(73) Assignee: Joulwatt Technology (Shanghai) Co., Ltd., Shanghai (CN)

(21) Appl. No.: 19/059,353

(22) Filed: Feb. 21, 2025

(30) Foreign Application Priority Data
Apr. 8, 2024 (CN) 202410418573.X

(51) Int. Cl. G01R 19/25

(52) U.S. Cl. CPC G01R 19/2509

(57) ABSTRACT

A voltage detection circuit, a voltage monitoring circuit, and a power supply and a control circuit thereof are provided. The voltage detection circuit is configured to detect a voltage between a positive sampling terminal and a negative sampling terminal, and includes: a first voltage-to-current (V-I) converter circuit connected to the positive sampling terminal and an output terminal of the voltage detection circuit, and configured to generate a first current flowing through the output terminal of the voltage detection circuit according to a positive sampling terminal voltage and a first voltage, where the first voltage is a voltage output from the output terminal of the voltage detection circuit; and a second V-I converter circuit connected to the negative sampling terminal, a reference ground and the output terminal of the voltage detection circuit, and configured to generate a second current flowing through the output terminal of the voltage detection circuit.

### CROSS-REFERENCE TO THE RELATED APPLICATIONS

This application is based upon and claims priority to Chinese Patent Application No. 202410418573.X, filed on Apr. 8, 2024, the entire contents of which are incorporated herein by reference.

### TECHNICAL FIELD

The present disclosure relates to the technical field of power electronics, and in particular to a voltage detection circuit, a voltage monitoring circuit, and a power supply and a control circuit thereof.

### BACKGROUND

As shown in FIG. 1, in response to a long distance between a power supply and the load, due to the voltage-dividing effect of transmission line resistor R_{WIRE} between the power supply and the load, load voltage V_{LOAD} is less than actual output voltage V_{OUT} of the power supply. Particularly for a high-current application scenarios, the transmission line resistor R_{WIRE} causes a large voltage drop. The power supply includes a power stage circuit and a control circuit. The power stage circuit is configured to output the output voltage V_{OUT}. In order to accurately control the load voltage and/or monitor the load voltage, a voltage detection circuit for detecting the load voltage V_{LOAD} is required in the control circuit.

The prior art provides a first type of voltage detection circuit 100. As shown in FIG. 2A, differential operational amplifier U1 is configured to convert load voltage V_{LOAD}, namely a voltage difference between positive sampling terminal voltage V_{OSP} and negative sampling terminal voltage V_{OSN}, into a single-ended voltage signal that takes reference ground GND as a reference. A voltage division circuit composed of two serially connected resistors is then configured to perform voltage division on the single-ended voltage signal to obtain sampling signal V_{sampling}. A control unit 40 in a control circuit of the power supply is configured to amplify an error between reference voltage Vref and the sampling signal V_{sampling} with error amplifier U2, and control an actual output voltage of the power supply according to signal Vc output from the error amplifier U2, thereby controlling the load voltage. According to the sampling signal V_{sampling}, information of the load voltage can be obtained accurately. Hence, the voltage detection circuit 100 can further be applied to the voltage monitoring circuit. Voltage monitoring unit 50 in the voltage monitoring circuit is configured to output a monitoring signal according to the sampling signal V_{sampling}. However, the voltage detection circuit 100 has the following defects: The speed of detection on the voltage between the positive sampling terminal and the negative sampling terminal completely depends on a bandwidth of the differential operational amplifier U1; the different bias voltages of the differential operational amplifier U1 under different common-mode voltages will affect the accuracy of detection on the voltage between the positive sampling terminal and the negative sampling terminal.

The prior art provides a second type of voltage detection circuit 200. As shown in FIG. 2B, a reference voltage generated by voltage source U4 is transferred to negative sampling terminal voltage V_{OSN}. Error amplifier U2 is configured to amplify an error between a voltage obtained by superposing the reference voltage to the negative sampling terminal voltage V_{OSN} and positive sampling terminal voltage V_{OSP}. A control circuit of the power supply is configured to control an actual output voltage of the power supply according to signal Vc output from the error amplifier U2. However, the voltage detection circuit 200 has the following defects: The reference voltage is generated on the negative sampling terminal voltage V_{OSN} to cause a complex circuit; according to the signal output from the error amplifier U2, the voltage information between the positive sampling terminal and the negative sampling terminal cannot be obtained accurately, therefore, the voltage between the positive sampling terminal and the negative sampling terminal cannot be monitored accurately.

### SUMMARY

In view of this, an objective of the present disclosure is to provide a voltage detection circuit, a voltage monitoring circuit, and a power supply and a control circuit thereof, to solve the technical problems that the speed of detection on the voltage between the positive sampling terminal and the negative sampling terminal completely depends on a bandwidth of the differential operational amplifier, and the different bias voltages of the differential operational amplifier under different common-mode voltages will affect the accuracy of detection on the voltage between the positive sampling terminal and the negative sampling terminal; or the reference voltage signal is generated on the negative sampling terminal voltage to cause a complex circuit, and the voltage information between the positive sampling terminal and the negative sampling terminal cannot be obtained accurately in the prior art.

The technical solutions of the present disclosure are as follows: According to a first aspect, the present disclosure provides a voltage detection circuit configured to detect a voltage between a positive sampling terminal and a negative sampling terminal, and including:
a first voltage-to-current (V-I) converter circuit connected to the positive sampling terminal and an output terminal of the voltage detection circuit, and configured to generate a first current flowing through the output terminal of the voltage detection circuit according to a positive sampling terminal voltage and a first voltage, where the first voltage is a voltage output from the output terminal of the voltage detection circuit; and
a second V-I converter circuit connected to the negative sampling terminal, a reference ground and the output terminal of the voltage detection circuit, and configured to generate a second current flowing through the output terminal of the voltage detection circuit according to a negative sampling terminal voltage.

Optionally, the first current flows to the output terminal of the voltage detection circuit; and the second current flows from the output terminal of the voltage detection circuit; and alternatively,

the first current flows from the output terminal of the voltage detection circuit; and the second current flows to the output terminal of the voltage detection circuit; and alternatively,

Optionally, the second current is proportional to the negative sampling terminal voltage.

Optionally, the first current is proportional to a difference between the positive sampling terminal voltage and the first voltage.

Optionally, a coefficient of proportionality of the first current to the difference between the positive sampling terminal voltage and the first voltage is equal to a coefficient of proportionality of the second current to the negative sampling terminal voltage.

Optionally, at the same time, a ratio of the first current to a difference between the positive sampling terminal voltage and the first voltage is equal to a ratio of the second current to the negative sampling terminal voltage.

Optionally, the first current is equal to the second current.

Optionally, the voltage detection circuit further includes:
a current source connected to the output terminal of the voltage detection circuit, to generate a third current flowing to or from the output terminal of the voltage detection circuit.

Optionally, the third current is adjustable.

Optionally, according to a Kirchhoff's law, a relation between the first voltage and a difference between the positive sampling terminal voltage and the negative sampling terminal voltage may be obtained.

Optionally, the second V-I converter circuit includes:
a first transistor including a first terminal connected to the output terminal of the voltage detection circuit;
a third resistor network including a first terminal connected to a second terminal of the first transistor, and a second terminal connected to the reference ground; and
a first operational amplifier including a first input terminal configured to receive the negative sampling terminal voltage, a second input terminal connected to the first terminal of the third resistor network, and an output terminal connected to a control terminal of the first transistor.

Optionally, the first V-I converter circuit includes:
a first resistor network including a first terminal configured to receive the positive sampling terminal voltage, and a second terminal connected to the output terminal of the voltage detection circuit.

Optionally,

$$V 1 = {V}_{OSP} - \frac{R 1}{R 3} {V}_{OSN} ,$$

where, V1 represents the first voltage, V_{OSP} represents the positive sampling terminal voltage, V_{OSN} represents the negative sampling terminal voltage, R1 represents a resistance of the first resistor network, and R3 represents a resistance of the third resistor network.

Optionally, the first V-I converter circuit further includes:
a second resistor network including a first terminal connected to the output terminal of the voltage detection circuit, and a second terminal connected to the reference ground.

Optionally,

$$V 1 = \frac{R 2}{R 1 + R 2} ( {V}_{OSP} - \frac{R 1}{R 3} {V}_{OSN} ) ,$$

where, V1 represents the first voltage, R1 represents a resistance of the first resistor network, R2 represents a resistance of the second resistor network, R3 represents a resistance of the third resistor network, V_{OSP} represents the positive sampling terminal voltage, and V_{OSN} represents the negative sampling terminal voltage.

Optionally, a resistance of the first resistor network is equal to a resistance of the third resistor network.

Optionally, the voltage detection circuit further includes a current source; and the current source includes:
a second transistor including a first terminal connected to the output terminal of the voltage detection circuit;
a fourth resistor network including a first terminal connected to a second terminal of the second transistor, and a second terminal connected to the reference ground; and
a second operational amplifier including a first input terminal configured to receive a second voltage, a second input terminal connected to the first terminal of the fourth resistor network, and an output terminal connected to a control terminal of the second transistor.

Optionally, the second voltage is adjustable.

Optionally, a ratio of a resistance of the first resistor network to a resistance of the fourth resistor network is adjustable.

Optionally, all or a part of the voltage detection circuit is integrated into a chip; and the reference ground of the voltage detection circuit serves as a reference ground of the chip.

According to a second aspect, the present disclosure further provides a voltage monitoring circuit, including an analog-to-digital converter (ADC) circuit, and the voltage detection circuit, where
the ADC circuit is configured to receive the first voltage output from the voltage detection circuit, and output a converted signal according to the first voltage; and
the voltage monitoring circuit is configured to output a voltage monitoring signal according to the converted signal.

According to a third aspect, the present disclosure further provides a control circuit applied to a power supply, where the control circuit includes an error amplifier and the voltage detection circuit;
the error amplifier includes a first input terminal configured to receive a reference voltage, a second input terminal configured to receive the first voltage output from the voltage detection circuit, and an output terminal configured to output a compensation signal; and
the control circuit is configured to output a control signal according to the compensation signal.

Optionally, the voltage detection circuit is configured to detect a voltage between two terminals of a load of the power supply.

According to a fourth aspect, the present disclosure further provides a power supply, where the power supply includes a power stage circuit and the control circuit; and
the control signal output from the control circuit is used to control a power transistor in the power stage circuit.

Optionally, the power supply includes a switching power supply; and the control signal is used to control on and off of the power transistor.

The circuit structure of the present disclosure has the following advantages over the prior art: The positive sampling terminal and the negative sampling terminal are unnecessarily connected to two input terminals of a differential operational amplifier respectively, most of voltage signals do not pass through the differential operational amplifier, the response of the first voltage is affected by the bandwidth of the operational amplifier little, so the bandwidth of the operational amplifier has little effect on the speed of detection on the voltage between the positive sampling terminal and the negative sampling terminal; the input common-mode voltage of the operational amplifier changes little, and the bias voltage is controlled easily; the reference voltage is not generated on the negative sampling terminal voltage V_{OSN}, but can be established on the reference ground of the chip, thereby achieving the simple circuit structure; the present disclosure can accurately obtain the voltage information between the positive sampling terminal and the negative sampling terminal, and can monitor the voltage between the positive sampling terminal and the negative sampling terminal.

### BRIEF DESCRIPTION OF THE DRAWINGS

FIG. 1 is a schematic diagram of connection between a power supply and a load;

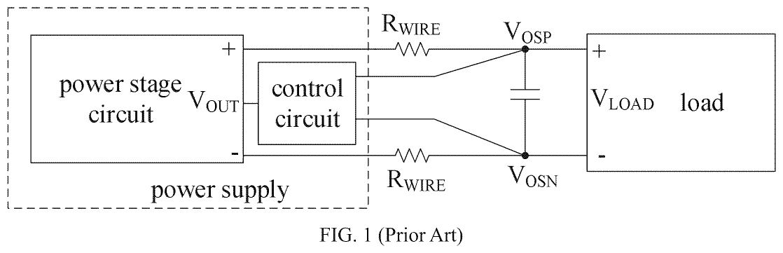

FIG. 2A is a schematic diagram of a circuit structure of a first type of voltage detection circuit according to a prior art;

FIG. 2B is a schematic diagram of a circuit structure of a second type of voltage detection circuit according to a prior art;

FIG. 3 is an electrical block diagram of a voltage detection circuit according to an embodiment of the present disclosure;

FIG. 4 is a schematic diagram of a circuit structure of the voltage detection circuit in FIG. 3 according to a first embodiment; and

FIG. 5 is a schematic diagram of a circuit structure of the voltage detection circuit in FIG. 3 according to a second embodiment.

### DETAILED DESCRIPTION OF THE EMBODIMENTS

The preferred embodiments of the present disclosure are described in detail below with reference to the drawings, but the present disclosure is not limited to these embodiments. The present disclosure covers any substitution, modification, equivalent method and solution made within the spirit and scope of the present disclosure.

For a thorough understanding of the present disclosure, the specific details of the following preferred embodiments of the present disclosure are explained hereinafter in detail, while the present disclosure can also be fully understood by those skilled in the art without the description of these details.

The present disclosure is described in detail by giving examples with reference to the drawings. It should be noted that the drawings are simplified and do not use an accurate proportion, that is, the drawings are merely for the objectives of conveniently and clearly assisting in illustrating embodiments of the present disclosure.

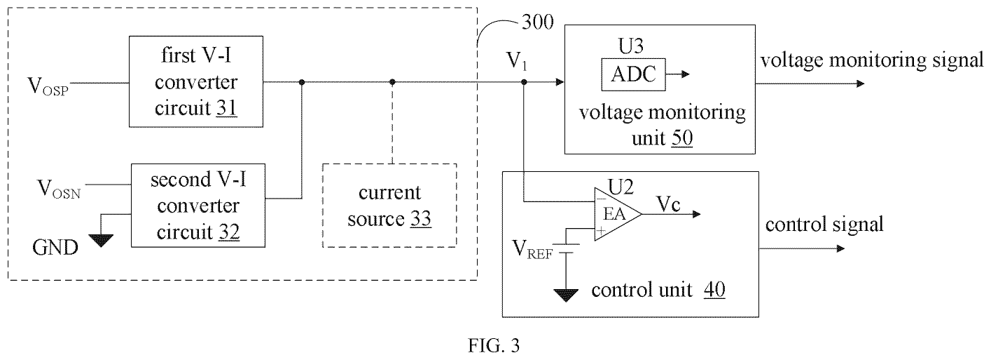

FIG. 3 is an electrical block diagram of voltage detection circuit 300 according to an embodiment of the present disclosure. The voltage detection circuit 300 is configured to detect a voltage between a positive sampling terminal and a negative sampling terminal. In some embodiments, the voltage detection circuit includes first V-I converter circuit 31 and second V-I converter circuit 32. The first V-I converter circuit 31 is connected to the positive sampling terminal and an output terminal of the voltage detection circuit, and configured to generate a first current flowing through the output terminal of the voltage detection circuit according to positive sampling terminal voltage V_{OSP} and first voltage V1. The first voltage V1 is a voltage output from the output terminal of the voltage detection circuit. The second V-I converter circuit 32 is connected to the negative sampling terminal, reference ground GND and the output terminal of the voltage detection circuit, and configured to generate a second current flowing through the output terminal of the voltage detection circuit according to negative sampling terminal voltage V_{OSN}. In an embodiment, the first current may flow to the output terminal of the voltage detection circuit, and the second current may flow from the output terminal of the voltage detection circuit. In another embodiment, the first current may also flow from the output terminal of the voltage detection circuit, and the second current may also flow to the output terminal of the voltage detection circuit. Specifically, the second current is associated with the negative sampling terminal voltage. The first current is associated with the positive sampling terminal voltage V_{OSP} and the first voltage V1. Further, in an embodiment, the second current may be proportional to the negative sampling terminal voltage V_{OSN}. In an embodiment, the first current may be proportional to a difference between the positive sampling terminal voltage V_{OSP} and the first voltage V1. Further still, in an embodiment, a coefficient of proportionality of the second current to the negative sampling terminal voltage V_{OSN} may be equal to a coefficient of proportionality of the first current to the difference between the positive sampling terminal voltage V_{OSP} and the first voltage V1. In another embodiment, at the same time, a ratio of the first current to a difference between the positive sampling terminal voltage and the first voltage is equal to a ratio of the second current to the negative sampling terminal voltage. According to a Kirchhoff's current law, the first current is equal to the second current, and thus a relation between the first voltage and the difference between the positive sampling terminal voltage and the negative sampling terminal voltage may be obtained. According to the first voltage, a voltage between positive sampling terminal and the negative sampling terminal can be accurately obtained. In other embodiments, the voltage detection circuit 300 further includes current source 33. The current source 33 is connected to the output terminal of the voltage detection circuit, to generate a third current flowing to or from the output terminal of the voltage detection circuit. Likewise, according to the Kirchhoff's current law, the relation between the first voltage and the difference between the positive sampling terminal voltage and the negative sampling terminal voltage can be obtained. While a magnitude and a direction of the third current are known, the voltage between positive sampling terminal and the negative sampling terminal can be accurately obtained according to the first voltage. Further, in an embodiment, the third current is adjustable.

Referring also to FIG. 3, an application example of the voltage detection circuit 300 in the embodiment of the present disclosure is further provided. On one hand, the voltage detection circuit 300 may be applied to a voltage monitoring circuit. In an embodiment, the voltage monitoring circuit includes the voltage detection circuit 300 and voltage monitoring unit 50. The voltage monitoring unit 50 is configured to output a voltage monitoring signal according to the first voltage V1 output from the voltage detection circuit 300. The voltage monitoring signal may be an indicator signal that indicates whether the voltage between the positive sampling terminal and the negative sampling terminal meets a requirement, and may also be a signal for displaying the voltage between the positive sampling terminal and the negative sampling terminal, which is not limited thereto in the present disclosure. Exemplarily, the voltage monitoring unit 50 includes ADC circuit U3. The ADC circuit U3 is configured to receive the first voltage V1, and output a converted signal according to the first voltage V1. The voltage monitoring unit 50 is configured to output the voltage monitoring signal according to the converted signal. The ADC circuit U3 may directly receive the first voltage V1, and may also receive a signal processed from the first voltage V1. The converted signal may be directly taken as the voltage monitoring signal to output, and may also be processed to take as the voltage monitoring signal to output, which is not limited thereto in the present disclosure. On the other hand, the voltage detection circuit 300 may also be applied to a control circuit of a power supply. In an embodiment, the power supply includes a power stage circuit and a control circuit. The control circuit includes the voltage detection circuit 300 and control unit 40. The voltage detection circuit 300 is configured to detect a voltage between two terminals of a load of the power supply. The control unit 40 includes error amplifier U2. The error amplifier U2 includes a first input terminal configured to receive reference voltage Vref, a second input terminal configured to receive the first voltage V1 output from the voltage detection circuit 300, and an output terminal configured to output compensation signal Vc. The control unit 40 is configured to output a control signal according to the compensation signal Vc. The control signal is used to control a power transistor in the power stage circuit of the power supply. The compensation signal Vc may be taken as the control signal to output, and a signal obtained by processing the compensation signal may also be taken as the output signal to output, which is not limited thereto in the present disclosure. It may be understood that in another embodiment, the control circuit may further include voltage monitoring unit 50, so as to control the power transistor in the power stage circuit of the power supply, and monitor the voltage between two terminals of the load. The power supply may be a linear power supply. The control signal is used to control a current flowing through the power transistor in the power stage circuit. The power supply may also be a switching power supply. The control signal is used to control on and off of the power transistor in the power stage circuit.

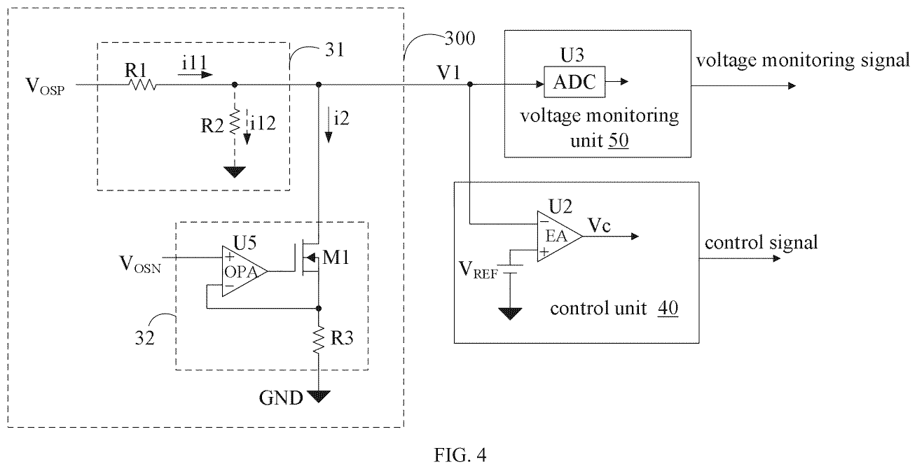

FIG. 4 is a schematic diagram of a circuit structure of the voltage detection circuit 300 according to a first embodiment of the present disclosure. The voltage detection circuit includes the first V-I converter circuit 31 and the second V-I converter circuit 32. Specifically, in an embodiment, the first V-I converter circuit 31 includes first resistor network R1. The first resistor network R1 includes a first terminal connected to the positive sampling terminal to receive the positive sampling terminal voltage V_{OSP}, and a second terminal connected to the output terminal of the voltage detection circuit. The second V-I converter circuit 32 includes first transistor M1, third resistor network R3, and first operational amplifier U5. The first transistor M1 includes a first terminal connected to the output terminal of the voltage detection circuit. The third resistor network R3 includes a first terminal connected to a second terminal of the first transistor, and a second terminal connected to the reference ground GND. The first operational amplifier U5 includes a first input terminal connected to the positive sampling terminal to receive the negative sampling terminal voltage V_{OSN}, a second input terminal connected to the first terminal of the third resistor network R3, and an output terminal connected to a control terminal of the first transistor M1. In the present disclosure, R1 represents the first resistor network, and R1 further represents a resistance of the first resistor network, and so on. In the embodiment, the first current generated by the first V-I converter circuit 31 and flowing to the output terminal of the voltage detection circuit is i11=(V_{OSP}−V1)/R1. The second current generated by the second V-I converter circuit 32 and flowing from the output terminal of the voltage detection circuit is i2=V_{OSN}/R3. According to the Kirchhoff's current law, i11=i2, namely (V_{OSP}−V1)/R1=V_{OSN}/R3, thereby obtaining:

$$V 1 = {V}_{OSP} - \frac{R 1}{R 3} {V}_{OSN} \qquad ( 1 )$$

In the foregoing Eq., V1 represents the first voltage, V_{OSP} represents the positive sampling terminal voltage, V_{OSN} represents the negative sampling terminal voltage, R1 represents the resistance of the first resistor network, and R3 represents a resistance of the third resistor network. In another embodiment, the first V-I converter circuit 31 further includes second resistor network R2. The second resistor network R2 includes a first terminal connected to the output terminal of the voltage detection circuit, and a second terminal connected to the reference ground GND. In the embodiment, the first current generated by the first V-I converter circuit 31 and flowing to the output terminal of the voltage detection circuit is i11−i12=(V_{OSP}−V1)/R1−V1/R3. According to the Kirchhoff's current law, i11−i12=i2, namely (V_{OSP}−V1)/R1−V1/R3=V_{OSN}/R3, thereby obtaining:

$$V 1 = \frac{R 2}{R 1 + R 2} ( {V}_{OSP} - \frac{R 1}{R 3} {V}_{OSN} ) \qquad ( 2 )$$

As can be seen from Eq. (1) and Eq. (2), the first voltage V1 can represent the difference between the positive sampling terminal voltage V_{OSP} and the negative sampling terminal voltage V_{OSN} in the embodiment.

Further, in other embodiments, the resistance R1 of the first resistor network may be equal to the resistance R3 of the third resistor network. Substituting R1=R3 into Eq. (1) may yield:

$$V 1 = {V}_{OSP} - {V}_{OSN} \qquad ( 3 )$$

As can be seen from Eq. (3), the voltage between the positive sampling terminal and the negative sampling terminal can be accurately obtained according to the first voltage V1 in the embodiment.

Substituting R1=R3 into Eq. (2) may yield:

$$V 1 = \frac{R 2}{R 1 + R 2} ( {V}_{OSP} - {V}_{OSN} ) \qquad ( 4 )$$

As can be seen from Eq. (4), in the embodiment, while the resistance R1 of the first resistor network and the resistance R2 of the second resistor network are known, or a ratio of the two resistances is known, the voltage between the positive sampling terminal and the negative sampling terminal can be accurately obtained according to the first voltage V1.

It may be understood that in other embodiments, the resistance R1 of the first resistor network and the resistance R3 of the third resistor network may also be variable resistances, provided that the resistance R1 of the first resistor network and the resistance R3 of the third resistor network are the same at the same time, namely Eq. (3) and Eq. (4) are ensured. The voltage between the positive sampling terminal and the negative sampling terminal can be accurately obtained according to the first voltage V1.

It may be understood that for the first current generated by the first V-I converter circuit 31 and flowing to the output terminal of the voltage detection circuit, and the second current generated by the second V-I converter circuit 32 and flowing from the output terminal of the voltage detection circuit in the embodiment, the direction of the first current and the direction of the second current can be changed by adding a current mirror or using other types of V-I converter circuits or the like in other embodiments, such that the first current flows from the output terminal of the voltage detection circuit, and the second current flows to the output terminal of the voltage detection circuit. This achieves the same technical effect as the embodiment.

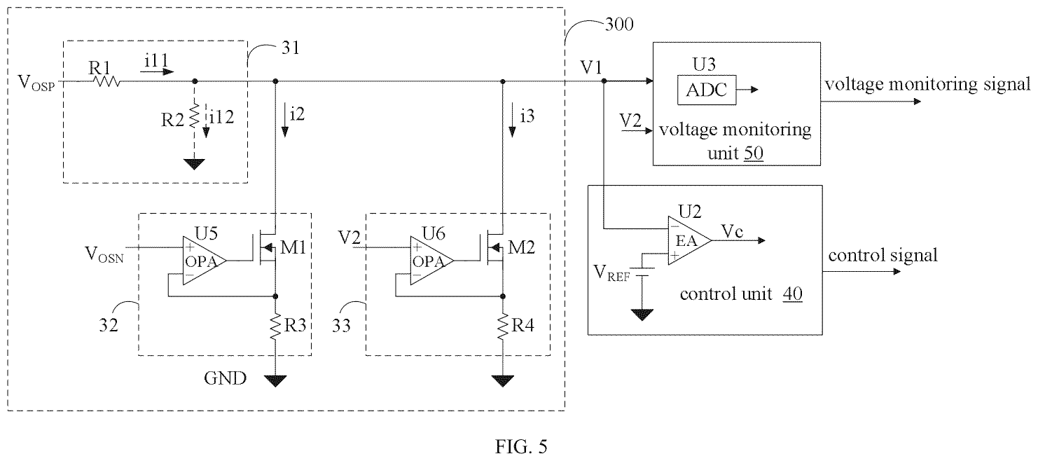

FIG. 5 is a schematic diagram of a circuit structure of the voltage detection circuit 300 according to a second embodiment of the present disclosure. The circuit structure of the voltage detection circuit in the embodiment is basically the same as that in the first embodiment, and is not repeated herein. The voltage detection circuit 300 in the embodiment further includes current source 33. The current source 33 is connected to the output terminal of the voltage detection circuit, to generate third current i3 flowing to or from the output terminal of the voltage detection circuit. Hereinafter, a case where the first V-I converter circuit 31 includes the second resistor network R2, and the third current i3 flows from the output terminal of the voltage detection circuit is used as an example to describe the embodiment. According to the Kirchhoff's current law, i11−i12=i2+i3, thereby obtaining:

$$V 1 = \frac{R 2}{R 1 + R 2} ( {V}_{OSP} - \frac{R 1}{R 3} {V}_{OSN} ) - \frac{R 1 \cdot R 2}{R 1 + R 2} i 3 \qquad ( 5 )$$

As can be seen from Eq. (5), the first voltage V1 can represent the difference between the positive sampling terminal voltage V_{OSP} and the negative sampling terminal voltage V_{OSN} in the embodiment.

Further, the resistance R1 of the first resistor network may be equal to the resistance R3 of the third resistor network. Substituting R1=R3 into Eq. (5) may yield

$$V 1 = \frac{R 2}{R 1 + R 2} ( {V}_{OSP} - {V}_{OSN} ) - \frac{R 1 \cdot R 2}{R 1 + R 2} i 3.$$

Therefore, while the resistance R1 of the first resistor network, the resistance R2 of the second resistor network and the third current i3 are known, the voltage between the positive sampling terminal and the negative sampling terminal can be accurately obtained according to the first voltage V1.

Specifically, in an embodiment, the current source 33 includes second transistor M2, fourth resistor network R4, and second operational amplifier U6. The second transistor M2 includes a first terminal connected to the output terminal of the voltage detection circuit. The fourth resistor network R4 includes a first terminal connected to a second terminal of the second transistor M2, and a second terminal connected to the reference ground GND. The second operational amplifier U6 includes a first input terminal configured to receive second voltage V2, a second input terminal connected to the first terminal of the fourth resistor network R4, and an output terminal connected to a control terminal of the second transistor M2. In the embodiment, the third current i3=V2/R4. With reference to the above analysis, the first voltage V1 can represent the difference between the positive sampling terminal voltage V_{OSP} and the negative sampling terminal voltage V_{OSN} in the embodiment. Further, when the resistance R1 of the first resistor network is equal to the resistance R3 of the third resistor network, the resistance R1 of the first resistor network, the resistance R2 of the second resistor network and the resistance R4 of the fourth resistor network are known (or a ratio of the three resistances is known), and the second voltage V2 is known, the voltage between the positive sampling terminal and the negative sampling terminal can be accurately obtained according to the first voltage V1.

Referring also to FIG. 5, when the voltage detection circuit 300 is applied to the control circuit of the power supply, the voltage detection circuit 300 may be configured to detect a voltage between two terminals of a load of the power supply. Through the error amplifier U2 in the control circuit, the first voltage V1 is stabilized at a voltage corresponding to the reference voltage Vref. Substituting V1=Vref into Eq. (5) may yield:

$${V}_{OSP} - \frac{R 1}{R 3} {V}_{OSN} = \frac{R 1 + R 2}{R 2} V ref + R 1 \cdot i 3 \qquad ( 6 )$$

As can be seen from Eq. (6), in the embodiment, while the reference voltage Vref is unchanged, namely the input of the error amplifier U2 is kept stable,

$${V}_{OSP} - \frac{R 1}{R 3} {V}_{OSN}$$

can be adjusted through the third current i3. Meanwhile, the amplitude of the

$${V}_{OSP} - \frac{R 1}{R 3} {V}_{OSN}$$

being adjusted by adjusting the third current i3 can be adjusted through the resistance R1 of the first resistor network.

Further, in an embodiment, the resistance R1 of the first resistor network may be equal to the resistance R3 of the third resistor network. Substituting R1=R3 into Eq. (6) may yield:

$${V}_{LOAD} = {V}_{OSP} - {V}_{OSN} = \frac{R 1 + R 2}{R 2} V ref + R 1 \cdot i 3 \qquad ( 7 )$$

In the foregoing Eq., V_{LOAD} represents the load voltage, namely the voltage between the two terminals of the load. According to Eq. (7), and with reference to the above analysis on Eq. (6), while keeping the input of the error amplifier U2 stable, the embodiment can adjust V_{OSP}−V_{OSN} through the third current i3, namely adjust the load voltage V_{LOAD} through the third current i3.

Further still, in an embodiment, the current source 33 includes second transistor M2, fourth resistor network R4, and second operational amplifier U6. The connection manner of the second transistor M2 has been described above, and is not repeated herein. In the embodiment, substituting the third current i3=V2/R4 into Eq. (7) may yield:

$${V}_{LOAD} = {V}_{OSP} - {V}_{OSN} = \frac{R 1 + R 2}{R 2} V ref + \frac{R 1}{R 4} \cdot V 2 \qquad ( 8 )$$

As can be seen from Eq. (8), in the embodiment, while the reference voltage Vref is unchanged, namely the input of the error amplifier U2 is kept stable, the load voltage V_{LOAD} can be adjusted through the second voltage V2. Meanwhile, the amplitude of the load voltage V_{LOAD} being adjusted by adjusting the second voltage V2 can be adjusted through a ratio of the resistance of the first resistor network to the resistance of the fourth resistor network.

It is easily understood that in other embodiments, referring to FIG. 5, the first V-I converter circuit 31 may also not include the second resistor network, and the third current i3 may also flow to the output terminal of the voltage detection circuit. Based on contents of the present disclosure, it can be readily conceivable for those skilled in the art to obtain the relation among the first voltage V1, the positive sampling terminal voltage V_{OSP} and the negative sampling terminal voltage V_{OSN} in these embodiments, and the description is not repeated herein.

At least a part of the voltage detection circuit, the voltage monitoring circuit and the control circuit of the power supply in the above embodiments may be integrated into a chip, which can achieve the obvious cost advantage. The reference ground of the voltage detection circuit may serve as a reference ground of the chip.

In addition, it is to be noted that the first resistor network, the second resistor network, the third resistor network and the fourth resistor network in the present disclosure may only include one independent resistor, and may also be a resistor network composed of a plurality of components.

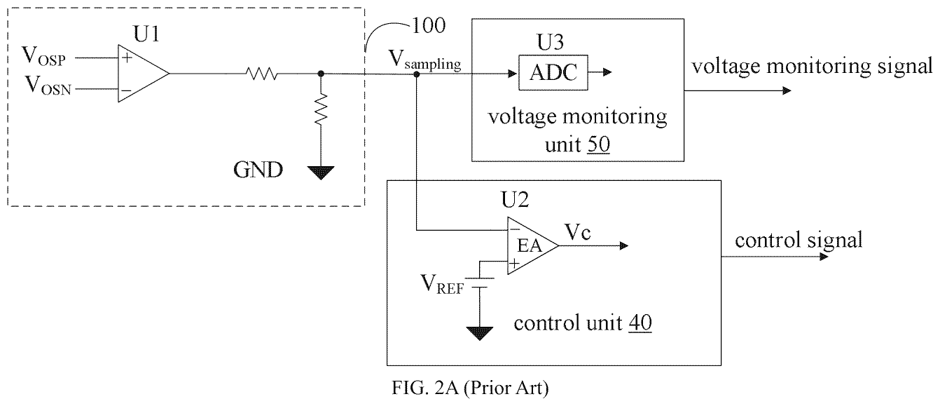

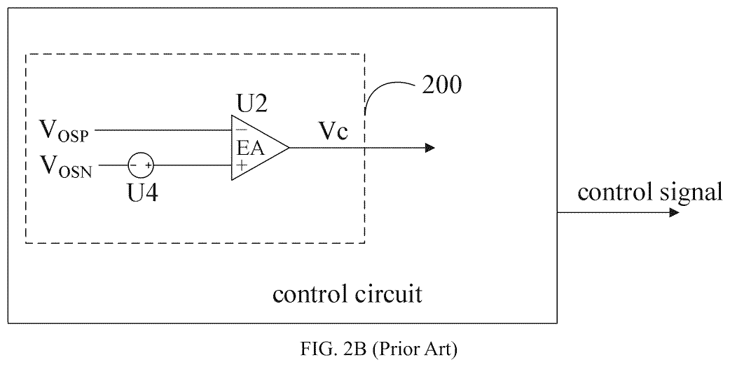

To sum up, compared with the first prior art shown in FIG. 2A, the voltage detection circuit 300 in the embodiment of the present disclosure does not need to respectively connect the positive sampling terminal and the negative sampling terminal to two input terminals of the differential operational amplifier, most of voltage signals do not pass through the first operational amplifier U5, the response of the first voltage is affected by the bandwidth of the first operational amplifier little, so the bandwidth of the first operational amplifier has little effect on the speed of detection on the voltage between the positive sampling terminal and the negative sampling terminal; in addition, the first operational amplifier U5 only receives the negative sampling terminal voltage and does not receive the positive sampling terminal voltage, so the input common-mode voltage changes little, and the bias voltage is controlled easily. Compared with the second prior art shown in FIG. 2B, the voltage detection circuit 300 in the embodiment of the present disclosure can accurately obtain the voltage information between the positive sampling terminal and the negative sampling terminal according to the first voltage, and thus can monitor the voltage between the positive sampling terminal and the negative sampling terminal; according to the control circuit of the power supply in the embodiment of the present disclosure, the reference voltage Vref is not generated on the negative sampling terminal voltage, but can be established on the reference ground of the chip, thereby achieving the simpler circuit structure. Meanwhile, when the voltage detection circuit 300 including the current source 33 in the embodiment of the present disclosure is applied to the control circuit of the power supply, while the input of the error amplifier U2 is kept stable, adjusting parameters of the current source 33 can adjust the load voltage V_{LOAD}.

The implementations described above do not constitute a limitation on the scope of protection of the technical solution of the present disclosure. Any modification, equivalent replacement, and improvement made in the spirit and principle of the above implementations should fall in the protection scope of the technical solution of the present disclosure.

What is claimed is:

1. A voltage detection circuit configured to detect a voltage between a positive sampling terminal and a negative sampling terminal, and comprising:
a first voltage-to-current (V-I) converter circuit connected to the positive sampling terminal and an output terminal of the voltage detection circuit, and configured to generate a first current flowing through the output terminal of the voltage detection circuit according to a positive sampling terminal voltage and a first voltage, wherein the first voltage is a voltage output from the output terminal of the voltage detection circuit; and
a second V-I converter circuit connected to the negative sampling terminal, a reference ground and the output terminal of the voltage detection circuit, and configured to generate a second current flowing through the output terminal of the voltage detection circuit according to a negative sampling terminal voltage.

2. The voltage detection circuit according to claim 1, wherein
the first current flows to the output terminal of the voltage detection circuit; and the second current flows from the output terminal of the voltage detection circuit; or
the first current flows from the output terminal of the voltage detection circuit; and the second current flows to the output terminal of the voltage detection circuit.

3. The voltage detection circuit according to claim 1, wherein the second current is proportional to the negative sampling terminal voltage.

4. The voltage detection circuit according to claim 3, wherein the first current is proportional to a difference between the positive sampling terminal voltage and the first voltage.

5. The voltage detection circuit according to claim 4, wherein a coefficient of proportionality of the first current to the difference between the positive sampling terminal voltage and the first voltage is equal to a coefficient of proportionality of the second current to the negative sampling terminal voltage.

6. The voltage detection circuit according to claim 1, wherein at the same time, a ratio of the first current to a difference between the positive sampling terminal voltage and the first voltage is equal to a ratio of the second current to the negative sampling terminal voltage.

7. The voltage detection circuit according to claim 1, wherein the voltage detection circuit further comprises:
a current source connected to the output terminal of the voltage detection circuit, to generate a third current flowing to or from the output terminal of the voltage detection circuit.

8. The voltage detection circuit according to claim 7, wherein
the third current is adjustable.

9. The voltage detection circuit according to claim 1, wherein according to a Kirchhoff's law, a relation between the first voltage and a difference between the positive sampling terminal voltage and the negative sampling terminal voltage is obtained.

10. The voltage detection circuit according to claim 1, wherein the second V-I converter circuit comprises:
a first transistor comprising a first terminal connected to the output terminal of the voltage detection circuit;
a third resistor network comprising a first terminal connected to a second terminal of the first transistor, and a second terminal connected to the reference ground; and
a first operational amplifier comprising a first input terminal configured to receive the negative sampling terminal voltage, a second input terminal connected to the first terminal of the third resistor network, and an output terminal connected to a control terminal of the first transistor.

11. The voltage detection circuit according to claim 10, wherein the first V-I converter circuit comprises:
a first resistor network comprising a first terminal configured to receive the positive sampling terminal voltage, and a second terminal connected to the output terminal of the voltage detection circuit.

12. The voltage detection circuit according to claim 11, wherein
$$V 1 = {V}_{OSP} - \frac{R 1}{R 3} {V}_{OSN} ,$$
wherein V1 represents the first voltage, V_{OSP} represents the positive sampling terminal voltage, V_{OSN} represents the negative sampling terminal voltage, R1 represents a resistance of the first resistor network, and R3 represents a resistance of the third resistor network.

13. The voltage detection circuit according to claim 11, wherein the first V-I converter circuit further comprises:
a second resistor network comprising a first terminal connected to the output terminal of the voltage detection circuit, and a second terminal connected to the reference ground.

14. The voltage detection circuit according to claim 13, wherein
$$V 1 = \frac{R 2}{R 1 + R 2} ( {V}_{OSP} - \frac{R 1}{R 3} {V}_{OSN} ) ,$$
wherein V1 represents the first voltage, R1 represents a resistance of the first resistor network, R2 represents a resistance of the second resistor network, R3 represents a resistance of the third resistor network, V_{OSP} represents the positive sampling terminal voltage, and V_{OSN} represents the negative sampling terminal voltage.

15. The voltage detection circuit according to claim 11, wherein
a resistance of the first resistor network is equal to a resistance of the third resistor network.

16. The voltage detection circuit according to claim 11, wherein the voltage detection circuit further comprises a current source; and the current source comprises:
a second transistor comprising a first terminal connected to the output terminal of the voltage detection circuit;
a fourth resistor network comprising a first terminal connected to a second terminal of the second transistor, and a second terminal connected to the reference ground; and
a second operational amplifier comprising a first input terminal configured to receive a second voltage, a second input terminal connected to the first terminal of the fourth resistor network, and an output terminal connected to a control terminal of the second transistor.

17. The voltage detection circuit according to claim 16, wherein
the second voltage is adjustable; and/or,
a ratio of a resistance of the first resistor network to a resistance of the fourth resistor network is adjustable.

18. The voltage detection circuit according to claim 1, wherein all or a part of the voltage detection circuit is integrated into a chip; and the reference ground of the voltage detection circuit serves as a reference ground of the chip.

19. A voltage monitoring circuit, comprising an analog-to-digital converter (ADC) circuit, and the voltage detection circuit according to claim 1, wherein
the ADC circuit is configured to receive the first voltage output from the voltage detection circuit, and output a converted signal according to the first voltage; and
the voltage monitoring circuit is configured to output a voltage monitoring signal according to the converted signal.

20. A control circuit applied to a power supply, comprising an error amplifier, and the voltage detection circuit according to claim 1, wherein
the voltage detection circuit is configured to detect a voltage between two terminals of a load of the power supply;
the error amplifier comprises a first input terminal configured to receive a reference voltage, a second input terminal configured to receive the first voltage output from the voltage detection circuit, and an output terminal configured to output a compensation signal; and
the control circuit is configured to output a control signal according to the compensation signal.
